(19) United States
(12) Patent Application Publication
(10) Pub. No.: US 2026/0223690 A1
(43) Pub. Date: Jul. 30, 2026

(54) MEMORY DEVICE AND METHOD FOR FORMING THE SAME

(71) Applicant: Yangtze Memory Technologies Co., Ltd., Wuhan (CN)

(72) Inventors: Zun Yang, Wuhan (CN); Cong Lu, Wuhan (CN); Zhenguo Wu, Wuhan (CN)

(21) Appl. No.: 19/091,339

(22) Filed: Mar. 26, 2025

Related U.S. Application Data
(63) Continuation of application No. PCT/CN2025/074717, filed on Jan. 24, 2025.

(51) Int. Cl. H01L 23/544

(52) U.S. Cl. CPC H10W 46/00; H10W 46/301

(57) ABSTRACT

A memory device and a fabrication method are provided. The memory device includes a bank in a bank region. The memory device further includes one or more first marks of a first type and one or more second marks of a second type. The one or more first marks and the one or more second marks are arranged in a peripheral region around the bank region.

### CROSS-REFERENCE TO RELATED APPLICATIONS

This application is a continuation of International Application No. PCT/CN2025/074717, filed on Jan. 24, 2025, which is hereby incorporated by reference in its entirety.

### TECHNICAL FIELD

The present disclosure generally relates to the field of semiconductor technology, and more particularly, to semiconductor devices and fabrication methods thereof.

### BACKGROUND

Fabrication of a three-dimensional (3D) memory device may include depositing and etching various semiconductor layers of different materials to form patterns in the semiconductor layers. During the manufacturing process, a current patterned layer needs to be aligned with a previous patterned layer in order to produce a functioning device. Overlay metrology (e.g., diffraction based overlay (DBO) metrology or image based overlay (IBO) metrology) can be used in the manufacturing process to measure and control this pattern-to-pattern alignment during fabrication of the 3D memory device.

### SUMMARY

In one aspect, a memory device includes a bank in a bank region. The memory device further includes one or more first marks of a first type and one or more second marks of a second type. The one or more first marks and the one or more second marks are arranged in a peripheral region around the bank region.

In some implementations, at least a first mark from the one or more first marks extends in a first direction, and a length of the first mark in the first direction is greater than a length of the first mark in a second direction intersected with the first direction. At least a second mark from the one or more second marks extends in the second direction, and a length of the second mark in the second direction is greater than a length of the second mark in the first direction.

In some implementations, the peripheral region includes: a first peripheral sub-region extending in the first direction; a second peripheral sub-region extending in the second direction intersected with the first direction, where the second peripheral sub-region connects to the first peripheral sub-region outside a first corner of the bank region; a third peripheral sub-region extending in the first direction, where the third peripheral sub-region connects to the second peripheral sub-region outside a second corner of the bank region; and a fourth peripheral sub-region extending in the second direction, where the fourth peripheral sub-region connects to the third peripheral sub-region outside a third corner of the bank region and connects to the first peripheral sub-region outside a fourth corner of the bank region.

In some implementations, the one or more first marks are arranged in at least one of the first peripheral sub-region or the third peripheral sub-region in the first direction, and the one or more second marks are arranged in at least one of the second peripheral sub-region or the fourth peripheral sub-region in the second direction.

In some implementations, the one or more first marks and the one or more second marks are arranged in at least one corner of the peripheral region.

In some implementations, the first mark includes a plurality of first mark units arranged in the first direction, where at least one of the first mark units extends in the second direction. The second mark includes a plurality of second mark units arranged in the second direction, where at least one of the second mark units extends in the first direction.

In some implementations, the at least one of the first mark units includes a first bar extending in the second direction, and the at least one of the second mark units includes a second bar extending in the first direction.

In some implementations, the at least one of the first mark units includes two or more first rectangles or first squares arranged in the second direction, and the at least one of the second mark units includes two or more second rectangles or second squares arranged in the first direction.

In some implementations, the plurality of first mark units include a first array of first mark units, a second array of first mark units, and a third array of first mark units. The second array of first mark units is arranged between the first and third arrays of first mark units in the first direction.

In some implementations, the first and third arrays of first mark units include a material different from that of the second array of first mark units.

In some implementations, the first and third arrays of first mark units include silicon oxide, tungsten (W), or copper (Cu). The second array of first mark units includes titanium nitride (TiN) and W.

In some implementations, the first and third arrays of first mark units are arranged in one or more semiconductor layers different from that of the second array of first mark units.

In some implementations, in the first direction, a distance between the first array of first mark units and the second array of first mark units is greater than a distance between two adjacent first mark units in the first or second array of first mark units.

In another aspect, a memory device includes a bank in a bank region and a mark arranged in a peripheral region that is around the bank region. The mark includes a first array of mark units, a second array of mark units, and a third array of mark units arranged in a first direction. The second array of mark units is arranged between the first array of mark units and the third array of mark units in the first direction.

In some implementations, a length of the mark in the first direction is greater than a length of the mark in a second direction intersected with the first direction.

In some implementations, the peripheral region includes: a first peripheral sub-region extending in the first direction; and a second peripheral sub-region extending in a second direction intersected with the first direction. The second peripheral sub-region connects to the first peripheral sub-region outside a corner of the bank region. The mark is arranged in the first peripheral sub-region.

In some implementations, at least one of the first, second, or third array of mark units includes a set of mark units arranged in the first direction. At least one of the mark units extends in a second direction intersected with the first direction.

In some implementations, the at least one of the mark units includes a bar extending in the second direction or two or more rectangles or squares arranged in the second direction.

In some implementations, the mark is arranged in a corner of the peripheral region.

In some implementations, the mark further includes: a fourth array of mark units arranged at a first end of the mark and adjacent to the first array of mark units in the first direction; and a fifth array of mark units arranged at a second end of the mark and adjacent to the third array of mark units in the first direction.

In some implementations, the first and third arrays of mark units include a first material different from a second material of the second array of mark units; or, the fourth and fifth arrays of mark units include a third material different from the first material of the first and third arrays of mark units or the second material of the second array of mark units.

In some implementations, the first and third arrays of mark units are arranged in one or more first semiconductor layers; the second array of mark units is arranged in one or more second semiconductor layers different from the one or more first semiconductor layers; and the fourth and fifth arrays of mark units are arranged in one or more third semiconductor layers different from at least one of the one or more first semiconductor layers or the one or more second semiconductor layers.

In some implementations, in the first direction, a distance between the first array of mark units and the second array of mark units is different from a distance between two adjacent mark units in the first or second array of mark units; or, a distance between the fourth array of mark units and the first array of mark units is different from a distance between two adjacent mark units in the first or fourth array of mark units.

In some implementations, in the first direction, the distance between the first array of mark units and the second array of mark units is greater than the distance between the two adjacent mark units in the first or second array of mark units; or, the distance between the fourth array of mark units and the first array of mark units is greater than the distance between the two adjacent mark units in the first or fourth array of mark units.

In still another aspect, a method for forming a memory device is disclosed. The method includes forming a mark in a peripheral region that is around a bank region. The mark includes a first array of mark units, a second array of mark units, and a third array of mark units arranged in a first direction. Forming the mark includes: forming one or more first semiconductor layers; forming, in the one or more first semiconductor layers, the first array of mark units and the third array of mark units in the peripheral region; forming one or more second semiconductor layers on the one or more first semiconductor layers; and forming, in at least one of the one or more first semiconductor layers or the one or more second semiconductor layers, the second array of mark units in the peripheral region. The second array of mark units is formed between the first array of mark units and the third array of mark units in the first direction.

In some implementations, a length of the mark in the first direction is greater than a length of the mark in a second direction intersected with the first direction.

In some implementations, forming the first array of mark units and the third array of mark units includes: forming, in the one or more first semiconductor layers, a first set of openings and a second set of openings arranged in the first direction; and forming the first array of mark units in the first set of openings, respectively, and the third array of mark units in the second set of openings, respectively.

In some implementations, forming the second array of mark units includes: forming, in the at least one of the one or more first semiconductor layers or the one or more second semiconductor layers, a third set of openings arranged in the first direction, where the third set of openings is formed between the first and third arrays of mark units in the first direction; and forming the second array of mark units in the third set of openings, respectively.

In some implementations, the one or more first semiconductor layers are formed on one or more third semiconductor layers. Forming the mark further includes forming, in the one or more third semiconductor layers, a fourth array of mark units at a first end of the mark and a fifth array of mark units at a second end of the mark in the first direction.

In some implementations, the mark is formed in a corner of the peripheral region.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1A illustrates a top view of an IBO mark formed on a memory device, according to some examples of the present disclosure.

FIG. 1B illustrates a top view of another IBO mark formed on a memory device, according to some examples of the present disclosure.

FIG. 1C illustrates a top view of a memory device including a plurality of IBO marks arranged in cutting streets of a memory device, according to some examples of the present disclosure.

FIG. 2 illustrates a top view of a bank of a 3D memory device, according to some aspects of the present disclosure.

FIG. 3A illustrates a top view of marks, according to some aspects of the present disclosure.

FIG. 3B illustrates a cross section of a mark of FIG. 3A, according to some aspects of the present disclosure.

FIGS. 3C-3D illustrate a top view of example implementations of a mark, according to some aspects of the present disclosure.

FIG. 3E illustrates a top view of another example implementation of a mark, according to some aspects of the present disclosure.

FIG. 3F illustrates a cross section of the mark of FIG. 3E, according to some aspects of the present disclosure.

FIG. 4A illustrates a top view of a first implementation of a memory device including a plurality of marks, according to some aspects of the present disclosure.

FIG. 4B illustrates an enlarged view of a first portion of the memory device of FIG. 4A, according to some aspects of the present disclosure.

FIG. 4C illustrates an enlarged view of a second portion of the memory device of FIG. 4A, according to some aspects of the present disclosure.

FIG. 4D illustrates a top view of a second implementation of a memory device including a plurality of marks, according to some aspects of the present disclosure.

FIG. 5 illustrates a top view of a memory device including a plurality of marks arranged in cutting streets of the memory device, according to some aspects of the present disclosure.

FIG. 6 illustrates a flowchart of a method for forming a memory device, according to some aspects of the present disclosure.

FIGS. 7A-7J illustrate a fabrication process for forming a memory device, according to some aspects of the present disclosure.

FIG. 8 illustrates a block diagram of an exemplary system having a 3D memory device, according to some aspects of the present disclosure.

FIG. 9A illustrates a diagram of an example memory card having a 3D memory device, according to some aspects of the present disclosure.

FIG. 9B illustrates a diagram of an example solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features, as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Semiconductor devices may include multiple patterned layers on a substrate. Each patterned layer may be fabricated through a series of process steps including, but not limited to, one or more material deposition steps, one or more lithography steps, and/or one or more etching steps. Features within each patterned layer need to be fabricated within selected tolerances to properly construct the final device. For example, overlay errors associated with relative displacement of features on different patterned layers need to be well characterized and controlled within each layer and relative to previously fabricated layers.

Overlay (OVL) measurement can be used to detect a degree of alignment accuracy between fabricated patterns of different sample layers during the lithography process, where a sample layer may include one or more semiconductive layers, and can be fabricated using one or more process steps to form a patterned layer having a fabricated pattern. A previously-fabricated sample layer can be referred to as a reference layer, whereas a currently-fabricated sample layer can be referred to as a target layer. In the process steps associated with the reference layer and the target layer, overlay marks (also referred to as “marks” for simplicity) may be formed on at least one of the reference layer or the target layer, and can be used to measure the alignment between the fabricated pattern of the reference layer and the fabricated patterned of the target layer. For example, an overlay mark may include fabricated features on the reference layer and/or the target layer, and can be arranged to facilitate overlay measurement between the reference layer and the target layer.

In some applications, IBO metrology may be applied to capture one or more images of overlay marks and determine an overlay error between the reference layer and the target layer based on relative positions of imaged features of the overlay marks on the layers of interest. Specifically, a high-resolution optical microscope (e.g., a scanning electron microscope (SEM), an atomic force microscope (AFM), or a scanning transmission electron microscope (STM)) may be used to perform the IBO measurement. Image recognition and image analysis can be performed on the captured images of the overlay marks to determine the overlay error. Then, the focus of lithography equipment can be adjusted based on the result of the overlay measurement to improve overlay alignment. For example, when the overlay error is greater than a preset threshold, a focus-correction value of the lithography equipment may be calculated based on the result of the overlay measurement, and then a position of the focus of the lithography equipment may be updated by adjusting a position of an exposure light source or a lens assembly.

In some examples, overlay marks used in the IBO metrology (also referred to as “IBO marks”) may include box-in-box (BIB) marks or advanced image metrology (AIM) marks. Since these IBO marks have a relatively large size (e.g., a size of 30 μm×30 μm or 28 μm×28 μm), they are only arranged in cutting streets of a memory device and cannot be arranged within the dies of the memory device. Further, each of these IBO marks is designed to have patterns that are used for two-dimensional (2D) overlay measurement. For example, the same IBO mark is used to measure both an X-direction overlay error and a Y-direction overlay error, and may be referred to as a 2D-overlay-measurement mark). Thus, flexibility in the design of the IBO mark is poor and locations where the IBO mark can be arranged in the memory device are very limited. Additionally, as the overlay requirement becomes more and more strict (e.g., an overlay error is required to be smaller than 4, 5, 7, or 10 nm), it is difficult for the large-size IBO marks which are arranged in the cutting streets to satisfy the high overlay requirement. On the other hand, even if the size of the IBO marks can be reduced such that they can be arranged within the dies, features in the IBO marks (e.g., a bar count and/or lengths of the bars in the IBO marks) need to greatly reduced in order to fit the IBO marks into small blank spaces in the dies, resulting in a degradation on the accuracy of the overlay measurement.

To address one or more of the aforementioned issues, the present disclosure introduces a solution in which small-size marks can be formed and arranged within the dies of a memory device. For example, compared with the above-mentioned IBO marks, one dimension (e.g., the X or Y dimension) of the marks disclosed herein can be reduced to have a length between 2 μm and 7 μm, which is much smaller than the length of 28 μm or 30 μm of the above-mentioned IBO marks. Thus, the marks disclosed herein can be arranged within small elongated blank regions (or elongated dummy regions) around banks of the respective dies. In some implementations, since one dimension of the marks is greatly reduced, the marks can be used for one-dimensional (1D) overlay measurement. For example, if the length of a first mark in the X-direction is reduced to be relatively small (e.g., between 2 μm and 7 μm), the first mark can be used to measure a Y-direction overlay error. If the length of a second mark in the Y-direction is reduced to be relatively small, the second mark can be used to measure an X-direction overlay error. The first or second mark may be referred to as a 1D-overlay-measurement mark. By utilizing both the first and second marks, 2D overlay measurement can be implemented.

The precision or accuracy of the overlay measurement using the marks disclosed herein is better than or at least comparable with the above-mentioned IBO marks (e.g., the AIM marks). Because one dimension of the marks disclosed herein is greatly reduced, the areas occupied by the marks can be greatly reduced, and the marks can be flexibly arranged in the memory device (e.g., within the respective dies or in the cutting streets of the memory device, which is not limited herein). If the marks are arranged within the respective dies, high-order compensation of the overlay measurement can be achieved when the number of the marks is sufficiently large (e.g., the number of the marks is larger than a predetermined threshold), resulting in improved accuracy on the overlay measurement.

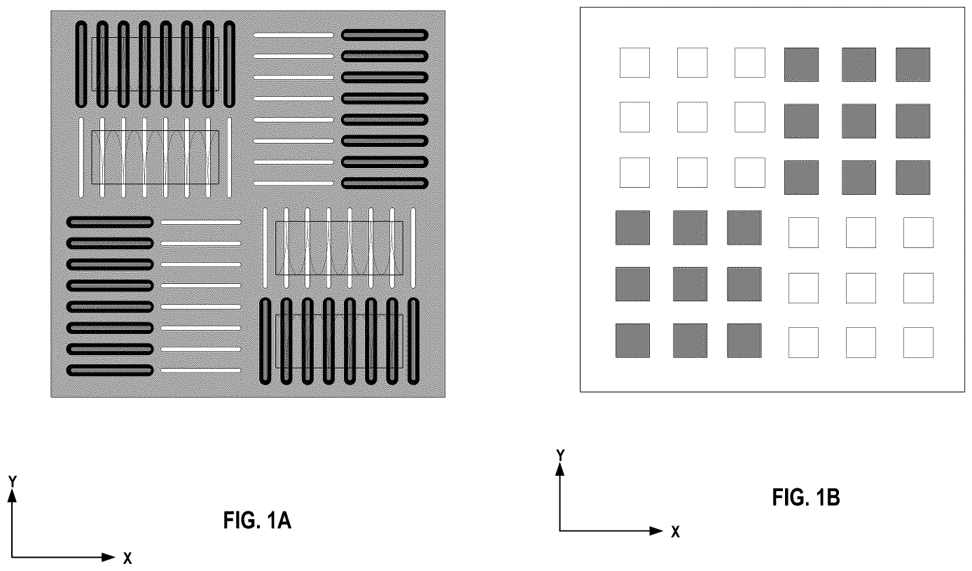

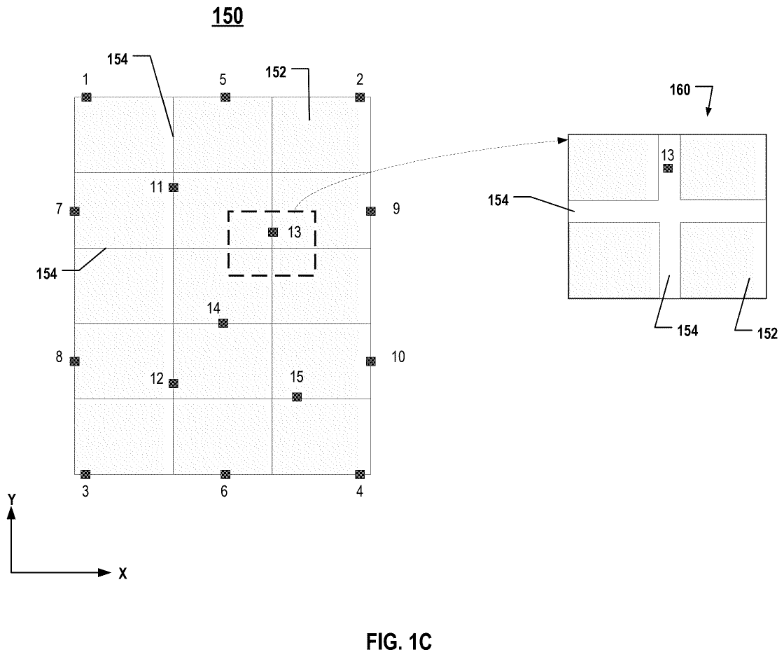

FIGS. 1A and 1B illustrate a top view of two IBO marks, respectively, according to some examples of the present disclosure. A size for the IBO mark shown in FIG. 1A or FIG. 1B is relatively large (e.g., 30 μm×30 μm or 28 μm×28 μm). These IBO marks are only arranged in the cutting streets of a memory device and cannot be arranged within the dies of the memory device due to their relatively large sizes. It is understood that the memory device may be cut into a plurality of dies along cutting streets. That is, the cutting streets can be locations along which the memory device is cut into the plurality of dies.

For example, as shown in FIG. 1C, a memory device 150 may include a plurality of dies 152 (3×5 dies) and a plurality of IBO marks (labeled using the numbers 1-15). Each IBO mark is arranged in a respective cutting street 154 of memory device 150 (e.g., the IBO mark 13 is arranged in cutting street 154 as shown in an enlarged portion 160 of memory device 150). Due to its large size, the IBO mark 13 cannot be placed within die 152.

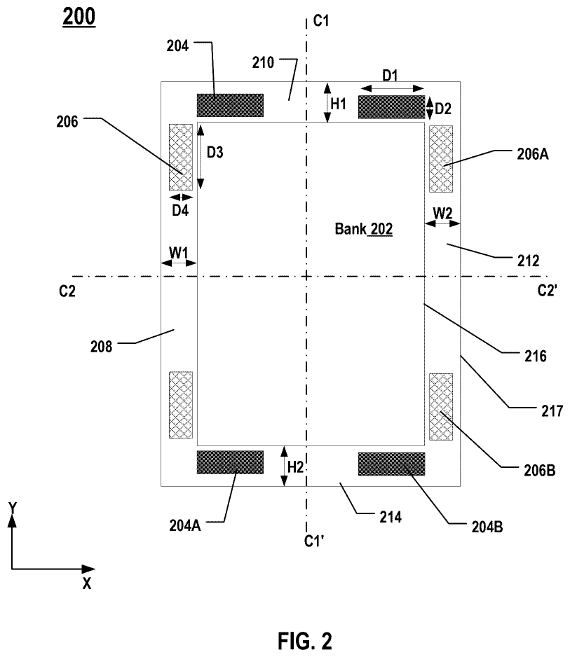

Further, the IBO mark shown in FIG. 1A or FIG. 1B is designed to have patterns that are used for 2D overlay measurement, resulting in poor flexibility in the design of the IBO mark and very limited locations where the IBO mark can be arranged in the memory device. As the overlay requirement becomes more and more strict (e.g., an overlay error is required to be smaller than 4, 5, 7, or 10 nm), it is difficult for the large-size IBO mark to satisfy the high overlay requirement. Consistent with some aspects of the present disclosure, small-size marks are disclosed herein with reference to FIGS. 2-7J below to address one or more of the aforementioned issues.

FIG. 2 illustrates a top view of a bank 202 of a 3D memory device 200, according to some aspects of the present disclosure. Memory device 200 may include bank 202 in a bank region 216. Although only one bank 202 is shown in FIG. 2, memory device 200 may include a plurality of banks 202, which is not limited herein. Bank 202 can be a unit of memory storage within memory device 200 that is constructed in parallel with other banks 202 in order to increase the throughput of the memory architecture. For example, in a DRAM chip, there are multiple banks. The double data rate 4 (DDR 4 ) specification allocates 4 bits to address banks, allowing for 16 banks per DRAM chip. Each bank is generally independent and can be in any phase of the access/refresh cycle. All banks have only one set of data pins. This configuration limits the DRAM chip to having only one bank transmitting or receiving data per clock cycle. It also allows for strong pipelining, which, under sufficient load, allows those data pins to be active on most (if not all) clock cycles rather than sitting idle while a new row opens.

Bank region 216 is surrounded by a peripheral region 217. For example, bank region 216 may be a region occupied by bank 202, whereas peripheral region 217 may be a blank region (or dummy region) surrounding bank region 216 and not occupied by bank 202. In some implementations, peripheral region 217 may include at least one of a first peripheral sub-region 208 extending in a first direction (e.g., the Y-direction), a second peripheral sub-region 210 extending in a second direction (e.g., the X-direction) intersected with the first direction, a third peripheral sub-region 212 extending in the Y-direction, or a fourth peripheral sub-region 214 extending in the X-direction. Second peripheral sub-region 210 connects to first peripheral sub-region 208 outside a first corner (e.g., an upper left corner) of bank region 216. Third peripheral sub-region 212 connects to second peripheral sub-region 210 outside a second corner (e.g., an upper right corner) of bank region 216. Fourth peripheral sub-region 214 connects to third peripheral sub-region 212 outside a third corner (e.g., a lower right corner) of bank region 216, and connects to first peripheral sub-region 208 outside a fourth corner (e.g., a lower left corner) of bank region 216. First, second, third, and fourth peripheral sub-regions 208, 210, 212, and 214 may be elongated blank regions (or elongated dummy regions) around bank region 216.

Memory device 200 may also include one or more first marks 206 of a first type and one or more second marks 204 of a second type. First marks 206 and second marks 204 are arranged in peripheral region 217. In some implementations, each second mark 204 extends in the X-direction, and a length D1 of second mark 204 in the X-direction is greater than a length D2 of second mark 204 in the Y-direction. For example, D1 is in a range between 12 μm and 35 μm (12 μm ≤D1≤35 μm), whereas D2 is in a range between 2 μm and 7 μm (2 μm≤D2≤7 μm). Each first mark 206 extends in the Y-direction, and a length D3 of first mark 206 in the Y-direction is greater than the length D4 of first mark 206 in the X-direction. For example, D3 is in a range between 12 μm and 35 μm (12 μm≤D3≤35 μm), whereas D4 is in a range between 2 μm and 7 μm (2 μm≤D4≤7 μm).

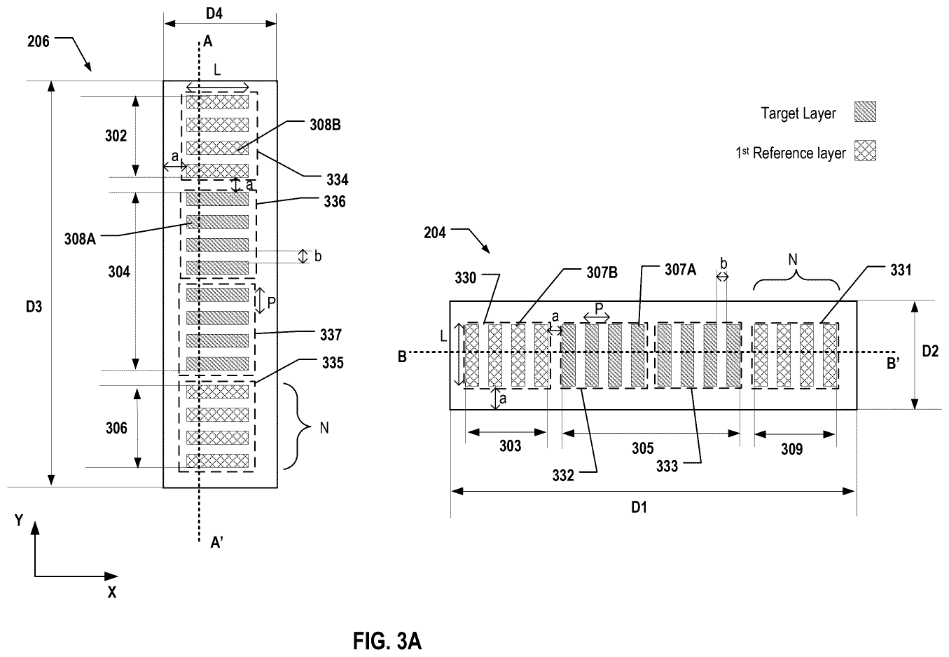

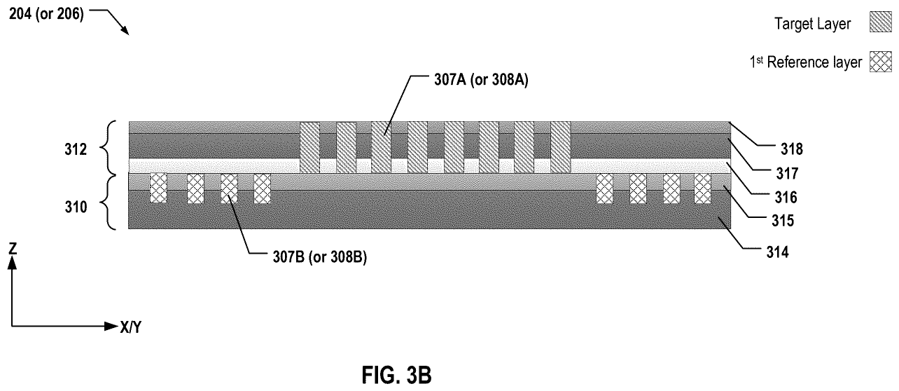

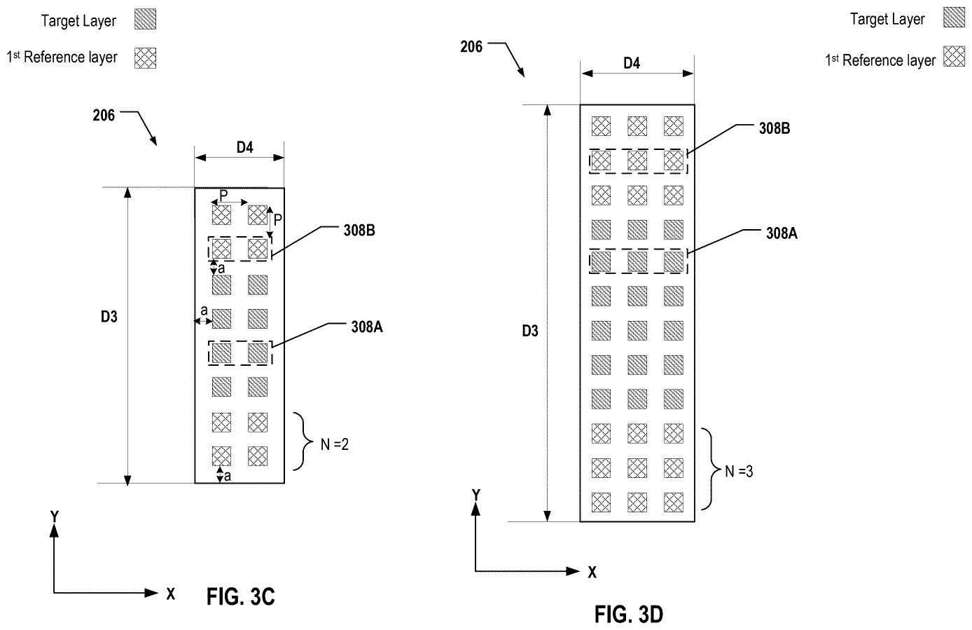

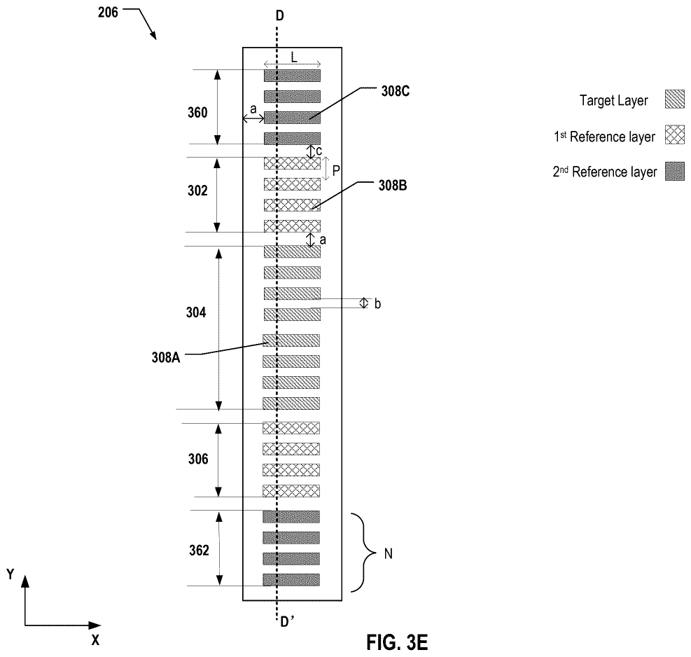

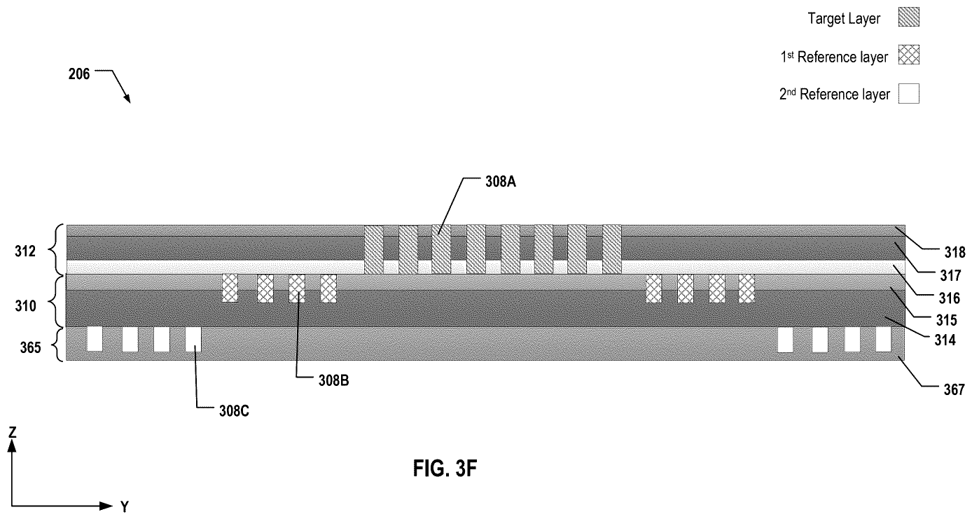

In some implementations, second mark 204 may have a structure like that of first mark 206 with D1=D3 and D2=D4, except that second mark 204 extends in the X-direction whereas first mark 206 extends in the Y-direction. When first mark 206 is rotated by 90 degrees in the X-Y plane, the rotated first mark 206 is identical to second mark 204. Thus, in some implementations, first mark 206 and second mark 204 can also be treated as marks of the same type. Detailed descriptions for first mark 206 or second mark 204 are provided below with reference to FIGS. 3A-3F.

First marks 206 are arranged in at least one of first peripheral sub-region 208 or third peripheral sub-region 212 in the Y-direction. For example, as shown in FIG. 2, first mark 206A and first mark 206B are arranged in third peripheral sub-region 212 in the Y-direction. In some implementations, the width W1 of first peripheral sub-region 208 in the X-direction and the width W2 of third peripheral sub-region 212 in the X-direction are greater than the length D4 of first mark 206 in the X-direction. For example, W1 or W2 may be in a range between 6 μm and 15 μm (e.g., W1 or W2=6 μm, 8.5 μm, 10 μm, 13 μm, or 15 μm), whereas D4 may be in a range between 2 μm and 7 μm (e.g., 2 μm≤D4≤7 μm). Then, as long as W1 or W2 is greater than D4, one or more first marks 206, each extending the Y-direction can be arranged within first peripheral sub-region 208 or third peripheral sub-region 212 in the Y-direction.

Second marks 204 are arranged in at least one of second peripheral sub-region 210 or fourth peripheral sub-region 214 in the X-direction. For example, as shown in FIG. 2, second mark 204A and second mark 204B are arranged in fourth peripheral sub-region 214 in the X-direction. In some implementations, the height H1 of second peripheral sub-region 210 in the Y-direction and the height H2 of fourth peripheral sub-region 214 in the Y-direction are greater than the length D2 of second mark 204 in the Y-direction. For example, H1 or H2 may be in a range between 6 μm and 15 μm (e.g., H1 or H2=6 μm, 8.5 μm, 10 μm, 13 μm, or 15 μm), whereas D2 may be in a range between 2 μm and 7 μm. Then, as long as H1 or H2 is greater than D2, one or more second marks 204, each extending the X-direction can be arranged within second peripheral sub-region 210 or fourth peripheral sub-region 214 in the X-direction.

In some implementations, first marks 206 and second marks 204 are arranged in corners of peripheral region 217. For example, a pair of first mark 206 and second mark 204 is arranged in a respective corner (e.g., the upper right corner, the upper left corner, the lower left corner, or the lower right corner) of peripheral region 217 as shown in FIG. 2. In some implementations, first marks 206 and second marks 204 are arranged to be symmetric relative to a center line C1-C1′ of bank region 216 in the X-direction. Alternatively or additionally, first marks 206 and second marks 204 are arranged to be symmetric relative to a center line C2-C2′ of bank region 216 in the Y-direction. In some other implementations, first marks 206 and second marks 204 are arranged to be unsymmetric relative to the center line C1-C1′ or the center line C2-C2′ of bank region 216, which is not limited herein.

FIG. 3A illustrates a top view of first mark 206 and second mark 204, according to some aspects of the present disclosure. FIG. 3B illustrates a cross section of first mark 206 along a line A-A′ or second mark 204 along a line B-B′ of FIG. 3A, according to some aspects of the present disclosure. Each first mark 206 may include a plurality of first mark units 308A, 308B (also referred to as 308, collectively or individually) arranged in the Y-direction, with each first mark unit 308 extending in the X-direction. Each second mark 204 may include a plurality of second mark units 307A, 307B (also referred to as 307, collectively or individually) arranged in the X-direction, with each second mark unit 307 extending in the Y-direction. For example, as shown in FIG. 3A, each first mark unit 308 of first mark 206 may include a first pattern (e.g., a first bar) extending in the X-direction, whereas each second mark unit 307 of second mark 204 may include a second pattern (e.g., a second bar) extending in the Y-direction.

In some implementations, with respect to first mark 206, the plurality of first mark units 308 may include a first array 302 of first mark units 308B, a second array 304 of first mark units 308A, and a third array 306 of first mark units 308B. Second array 304 of first mark units 308A is arranged between first and third arrays 302, 306 of first mark units 308B in the Y-direction from a top view. For example, first and third arrays 302, 306 of first mark units 308B may include patterns formed by one or more first process steps associated with a first reference layer 310 (shown in FIG. 3B), whereas second array 304 of first mark units 308A may include patterns formed by one or more second process steps associated with a target layer 312 (shown in FIG. 3B).

Similarly, with respect to second mark 204, the plurality of second mark units 307 may include a first array 303 of second mark units 307B, a second array 305 of second mark units 307A, and a third array 309 of second mark units 307B. Second array 305 of second mark units 307A is arranged between first array 303 and third array 309 of second mark units 307B in the X-direction from a top view. For example, first and third arrays 303, 309 of second mark units 307B may include patterns formed by the one or more first process steps associated with first reference layer 310, whereas second array 305 of second mark units 307A may include patterns formed by the one or more second process steps associated with target layer 312.

With respect to first mark 206, a distance between first mark unit 308 and a boundary of first mark 206 (e.g., a left boundary, a right boundary, a top boundary, or a bottom boundary of first mark 206) is denoted by “a,” where “a” may have a value between 0.3 μm and 1 μm (0.3 μm≤a≤1 μm) or any other suitable value. A length L of first mark unit 308 in the X-direction may have a value between 2 μm and 7 μm (2 μm≤L≤7 μm) or any other suitable value. The length D4 of first mark unit 308 in the X-direction may also have a value between 2 μm and 7 μm (e.g., 2 μm≤D4≤7 μm) or any other suitable value. A pitch P of first mark units 308 in first array 302, second array 304, or third array 306 may have a value between 1 μm and 1.8 μm or any other suitable value. The number of first mark units 308 in first array 302 or third array 306 is denoted by “N,” where N may be a positive integer such as 2, 3, 4, 5, or any other suitable integer. The number of first mark units 308 in second array 304 can be 2N. In some implementations, the distance between first array 302 and second array 304 (or the distance between second array 304 and third array 306) is greater than a distance “b” between two adjacent first mark units 308 in first array 302, second array 304, or third array 306. For example, the distance between first array 302 and second array 304 is equal to “a,” with a>b. In some other implementations, the distance between first array 302 and second array 304 (or the distance between second array 304 and third array 306) is equal to or smaller than the distance “b” between two adjacent first mark units 308 in first array 302, second array 304, or third array 306, which is not limited herein.

Consistent with some aspects of the present disclosure, first mark 206 and second mark 204 can be treated as marks of the same type. For example, when first mark 206 is rotated by 90 degrees in the X-Y plane, the rotated first mark 206 may become second mark 204 (e.g., a rotated first mark unit 308 becomes a corresponding second mark unit 307). Parameters “a,” “b,” “L,” “N,” and “P” of second mark 204 may be like corresponding parameters of first mark 206, and a similar description will not be repeated herein.

In some implementations, the length D4 of first mark 206 in the X-direction is much smaller than the length D3 of first mark 206 in the Y-direction (e.g., 12 μm≤D3≤35 μm, 2 μm≤D4≤7 μm). First mark 206 may not be used to measure an X-direction overlay error, but can be used to measure a Y-direction overlay error. The length D2 of second mark 204 in the Y-direction is much smaller than the length D1 of second mark 204 in the X-direction (e.g., 12 μm≤D1≤35 μm, 2 μm≤D2≤7 μm). Second mark 204 may not be used to measure the Y-direction overlay error, but can be used to measure the X-direction overlay error. First mark 206 or second mark 204 may be referred to as a 1D-overlay-measurement mark. By utilizing both first and second marks 206 and 204, 2D overlay measurement can be implemented.

For example, by using second mark 204, a measured reference point associated with first reference layer 310 in the X-direction can be calculated using (i) a pattern 330 formed by first array 303 of second mark units 307B and (ii) a pattern 331 formed by third array 309 of second mark units 307B (e.g., the measured reference point in the X-direction can be a middle point between pattern 330 and pattern 331 in the X-direction). A measured target point associated with target layer 312 in the X-direction can be calculated using a pattern 332 formed by a first part of second array 305 and a pattern 333 formed by a second part of second array 305 (e.g., the measured target point in the X-direction can be a middle point between pattern 332 and pattern 333 in the X-direction). Then, an X-direction overlay error can be calculated based on a difference between the measured reference point in the X-direction and the measured target point in the X-direction.

On the other hand, by using first mark 206, a measured reference point associated with first reference layer 310 in the Y-direction can be calculated using a pattern 334 formed by first array 302 of first mark units 308B and a pattern 335 formed by third array 306 of first mark units 308A (e.g., the measured reference point in the Y-direction can be a middle point between pattern 334 and pattern 335 in the Y-direction). A measured target point associated with target layer 312 in the Y-direction can be calculated using a pattern 336 formed by a first part of second array 304 and a pattern 337 formed by a second part of second array 304 (e.g., the measured target point in the Y-direction can be a middle point of pattern 336 and pattern 337). Then, a Y-direction overlay error can be calculated based on a difference between the measured reference point in the Y-direction and the measured target point in the Y-direction.

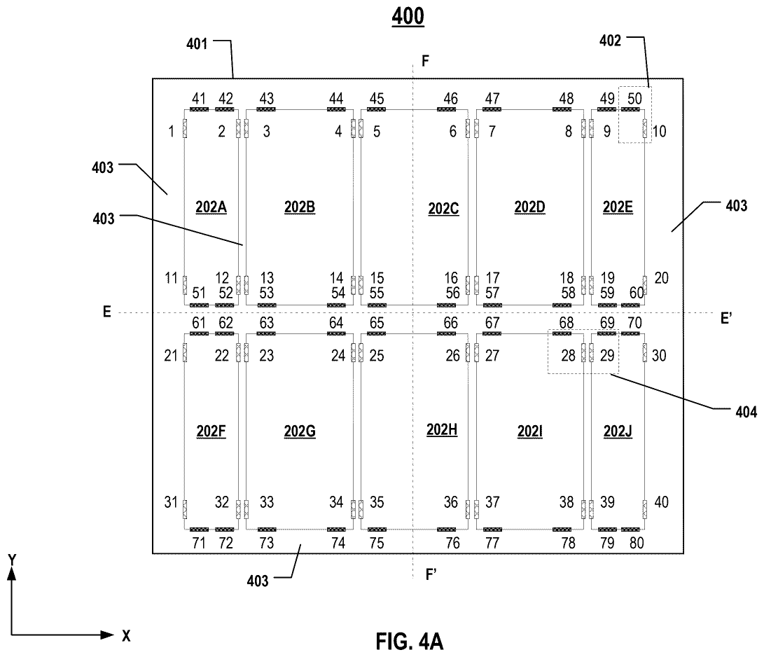

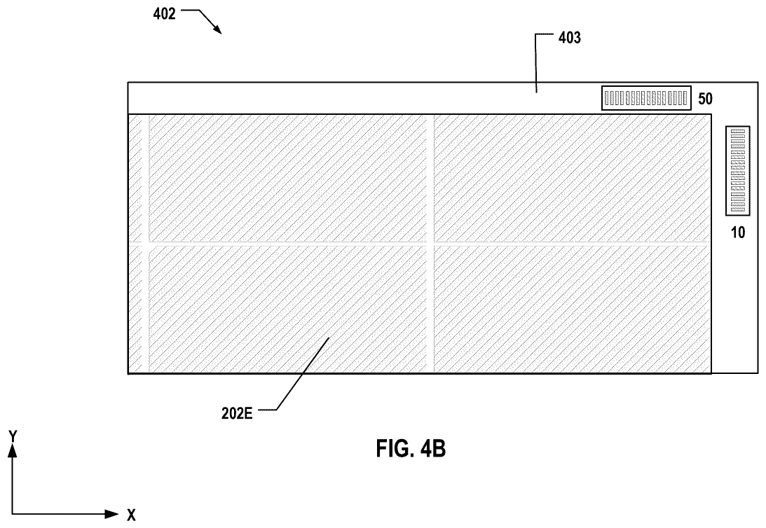

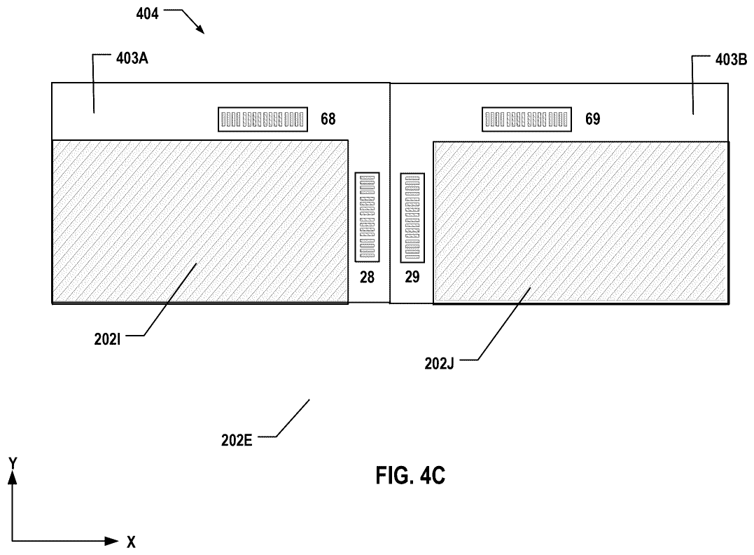

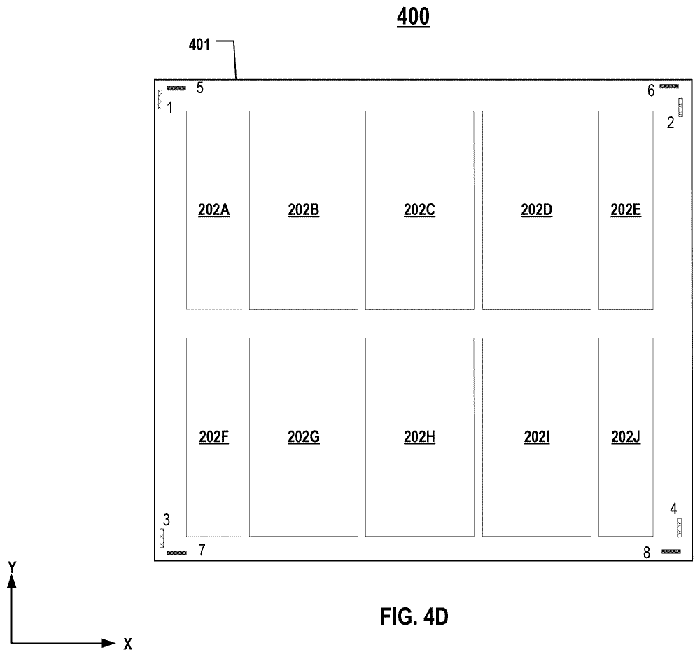

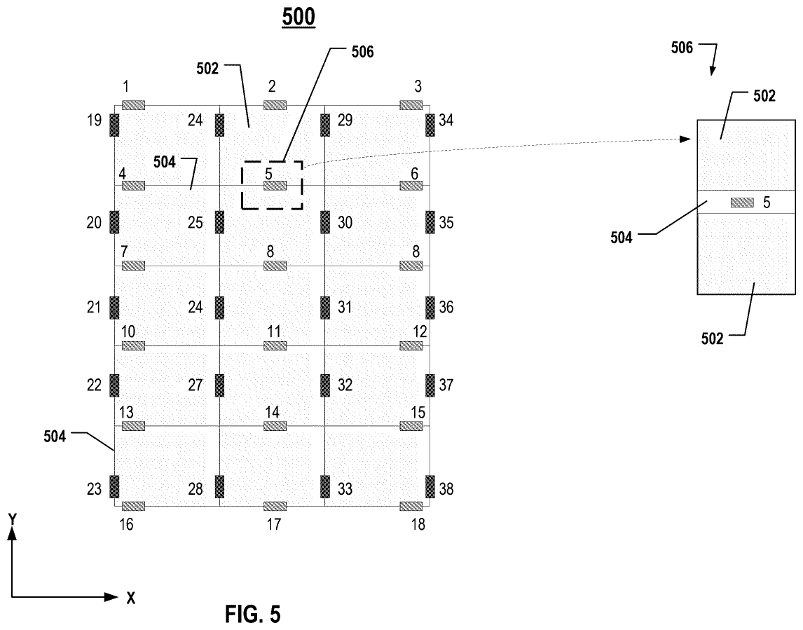

In some implementations, each first mark unit 308 or each second mark unit 307 can be divided into segmentations to improve the precision of the overlay measurement. In some implementations, parameters of first mark unit 308 (or second mark unit 307), such as the length L, the number N, and the pitch P, etc., can be adjusted to balance (i) the length D4 (or D2) and (ii) the length D3 (or D1) based on actual needs, thereby improving the flexibility of the mark design. For example, with respect to first mark 206, the length D3 in the Y-direction may be increased by increasing the number N (e.g., thereby increasing the number of first mark units 308), whereas the length D4 in the X-direction may be decreased by reducing the length L of first mark units 308 in the X-direction. In another example, the length L of first mark units 308 in the X-direction can be increased, whereas the number N can be reduced, thereby reducing the length D3 in the Y-direction. In some implementations, first mark 206 and second mark 204 are in-die marks, and can be arranged within respective dies of memory device 200, as shown in FIG. 2 and FIGS. 4A-4D below. In some implementations, first mark 206 and second mark 204 can be arranged in cutting streets between respective dies of memory device 200 as shown in FIG. 5 below.

In some implementations, with respect to first mark 206, first array 302, and third array 306 of first mark units 308B may include a material different from that of second array 304 of first mark units 308A. For example, first array 302 and third array 306 of first mark units 308B may include silicon oxide, tungsten (W), or copper (Cu), whereas second array 304 of first mark units 308A may include titanium nitride (TiN) and tungsten (W). Alternatively, first array 302 and third array 306 of first mark units 308B may include the same material as that of second array 304 of first mark units 308A. It is contemplated that the material of first mark units 308A or 308B can be determined according to the actual process steps needed to form respective patterns in target layer 312 and first reference layer 310, and the material of first mark units 308A or 308B is not limited herein.

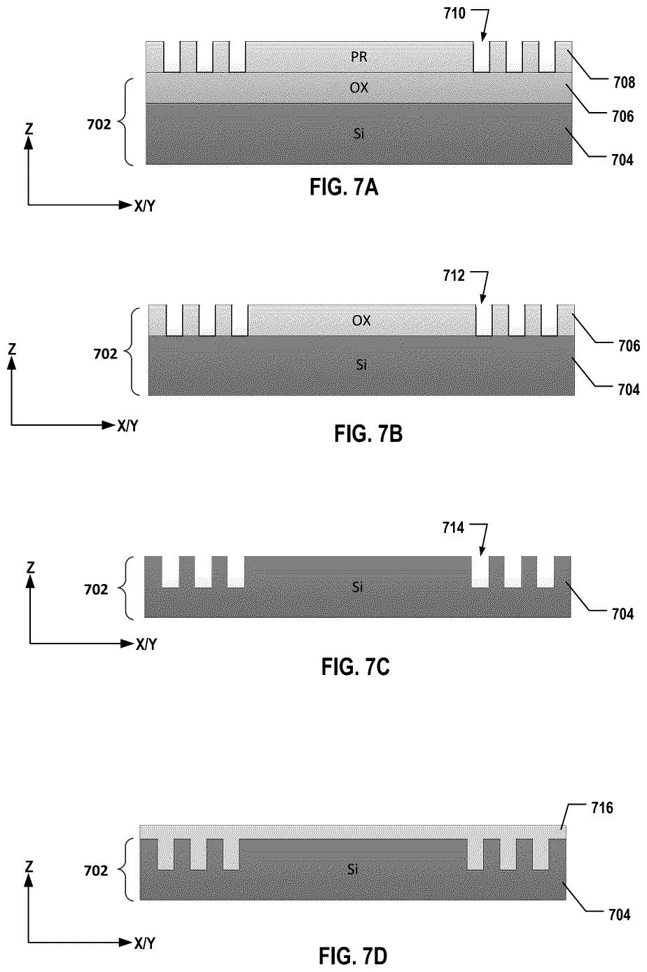

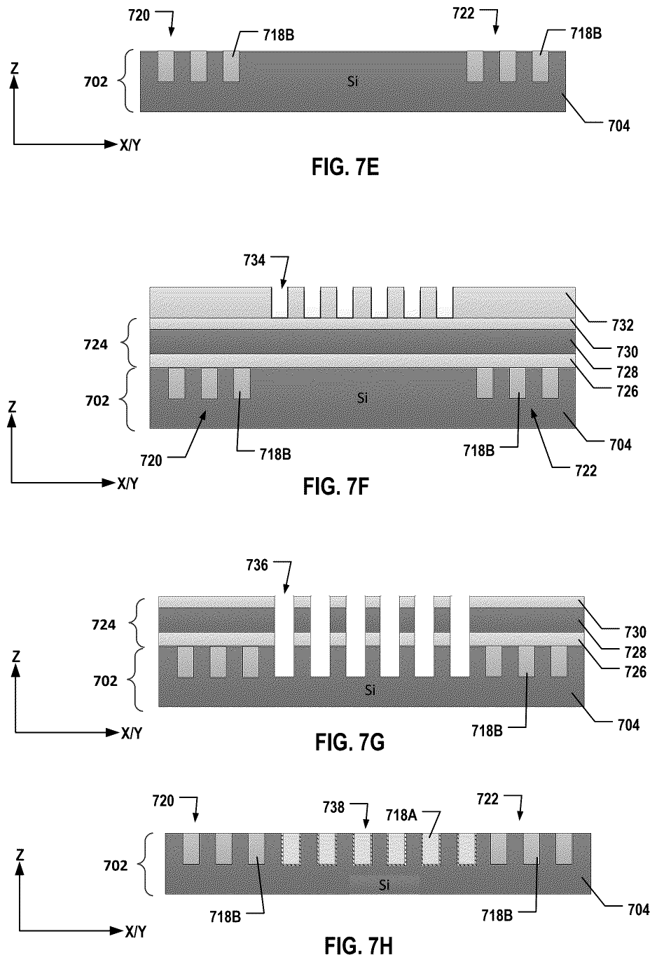

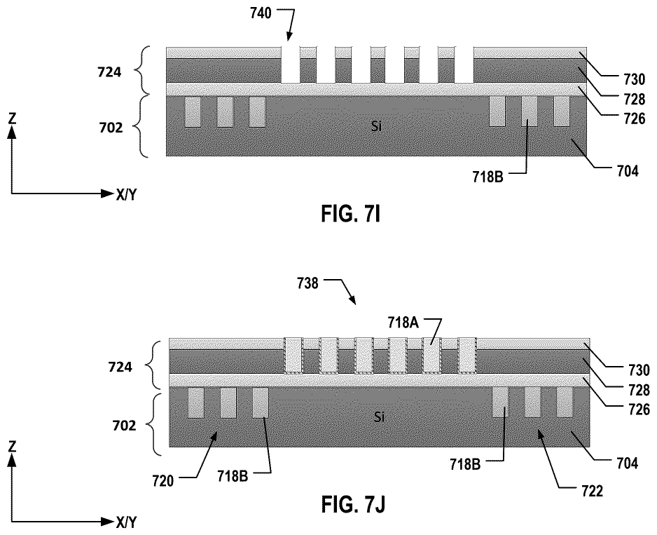

In some implementations, first mark units 308B in first array 302 and third array 306 may be arranged in one or more semiconductor layers different from that of first mark units 308A in second array 304. For example, referring to FIG. 3B, first reference layer 310 may include one or more semiconductor layers (e.g., semiconductor layers 314 and 315). First mark units 308B in first array 302 and third array 306 may be formed in semiconductor layers 314 and 315. Target layer 312 may include semiconductor layers 316, 317, and 318. First mark units 308A in second array 304 may be formed in semiconductor layers 316, 317, and 318. In some other implementations, first mark units 308B in first array 302 and third array 306 may be arranged in the same semiconductor layer(s) as first mark units 308A in second array 304 (e.g., as shown in FIG. 7H below). That is, first mark units 308A and 308B may be arranged in the same semiconductor layer(s) or different semiconductor layers according to the actual process steps needed to form respective patterns in target layer 312 and first reference layer 310, which is not limited herein.

Similarly, with respect to second mark 204, first array 303, and third array 309 of second mark units 307B may include a material different from that of second array 305 of second mark units 307A. For example, first array 303 and third array 309 of second mark units 307B may include silicon oxide, tungsten (W), or copper (Cu), whereas second array 305 of second mark units 307A may include titanium nitride (TiN) and tungsten (W). Alternatively, first array 303 and third array 309 of second mark units 307B may include the same material as that of second array 305 of second mark units 307A. It is contemplated that the material of second mark units 307A or 307B can be determined according to the actual process steps as needed to form respective patterns in first reference layer 310 and target layer 312, and the material of second mark units 307A or 307B is not limited herein.

In some implementations, second mark units 307B in first array 303 and third array 309 may be arranged in one or more semiconductor layers different from that of second mark units 307A in second array 305. For example, referring to FIG. 3B, second mark units 307B in first array 303 and third array 309 may be formed in semiconductor layers 314 and 315 of first reference layer 310. Second mark units 307A in second array 305 may be formed in semiconductor layers 316, 317, and 318 of target layer 312. In some other implementations, second mark units 307B in first array 303 and third array 309 may be arranged in the same semiconductor layer(s) as second mark units 307A in second array 305 (e.g., as shown in FIG. 7H below).

Comparing first mark 206 with second mark 204, first mark units 308B of first mark 206 may have the same material and formed in the same semiconductor layers as second mark units 307B of second mark 204, because first mark units 308B and second mark units 307B are formed by the same process step(s) when patterns in target layer 312 are formed. Similarly, first mark units 308A of first mark 206 may have the same material and formed in the same semiconductor layers as second mark units 307A of second mark 204, because first mark units 308A and second mark units 307A are formed by the same process step(s) when patterns in first reference layer 310 are formed.

FIGS. 3C-3D illustrate a top view of example implementations of a mark (e.g., first mark 206), according to some aspects of the present disclosure. First mark 206 shown in FIGS. 3C-3D may have components like those described above with reference to FIGS. 3A-3B, and a similar description will not be repeated herein. In FIGS. 3A-3B, each first mark unit 308 (308A, 308B) includes a bar extending in the X-direction, whereas each first mark unit 308 in FIGS. 3C-3D includes two or more separate rectangles (or squares) arranged in the X-direction. A pitch of the two or more separate rectangles (or squares) is also P, identical to the pitch of first mark units 308 in first array 302, second array 304, or third array 306 of FIGS. 3A-3B. In FIGS. 3C-3D, the length D3 of first mark 206 in the Y-direction may be in a range between 7.5 μm and 35 μm, and the length D4 of first mark 206 in the X-direction may be in a range between 1.5 μm and 8.5 μm.

In some implementations, each rectangle or square in first mark unit 308 shown in FIGS. 3C-3D can be divided into segmentations to improve the precision of the overlay measurement. In some implementations, parameters of first mark unit 308 (such as the length L, the number N, the pitch P, or the number of rectangles or squares in each first mark unit 308, which is denoted as Q) can be adjusted as actual needed. In some implementations, Q is equal to N.

In some implementations, first mark 206 shown in FIGS. 3C-3D may be used to measure both an X-direction overlay error and a Y-direction overlay error. First mark 206 shown in FIGS. 3C-3D may be referred to as a 2D-overlay-measurement mark. In some implementations, first mark 206 shown in FIGS. 3C-3D can be arranged within respective dies of memory device 200, or in cutting streets between respective dies of memory device 200. When first mark 206 shown in FIGS. 3C-3D is rotated by 90 degrees, and the rotated first mark 206 becomes second mark 204 (e.g., a rotated first mark unit 308 becomes a corresponding second mark unit 307). As a result, each second mark unit 307 of second mark 204 includes two or more rectangles or squares arranged in the Y-direction (rather than having a bar extending in the Y-direction as shown in FIG. 3A). The similar description for second mark 204 will not be repeated herein.

FIG. 3E illustrates a top view of another example implementation of a mark (e.g., first mark 206), according to some aspects of the present disclosure. FIG. 3F illustrates a cross section of the mark along a line D-D′ of FIG. 3E, according to some aspects of the present disclosure. First mark 206 shown in FIGS. 3E-3F may have components like those described above with reference to FIGS. 3A-3B, and a similar description will not be repeated herein.

As shown in FIG. 3E, first mark 206 may further include a fourth array 360 of first mark units 308C and a fifth array 362 of first mark units 308C. Fourth array 360 of first mark units 308C can be arranged at a first end of the mark (e.g., an upper end of the mark), and adjacent to first array 302 of first mark units 308B in the Y-direction. Fifth array 362 of first mark units 308C can be arranged at a second end of the mark (e.g., a lower end of the mark), and adjacent to third array 306 of first mark units 308B in the Y-direction.

The number of first mark units 308C in fourth array 360 or fifth array 362 can be equal to the number of first mark units 308B in first array 302 or third array 306, and is also denoted by “N,” where N may be a positive integer such as 2, 3, 4, 5, or any other suitable integer. The number of first mark units 308A in second array 304 can be 2N.

In some implementations, the distance “a” between first array 302 and second array 304 in the Y-direction can be different from a distance “b” between two adjacent first mark units 308 in first array 302 or second array 304 in the Y-direction. For example, the distance “a” between first array 302 and second array 304 is greater than the distance “b” between two adjacent first mark units 308 in first array 302 or second array 304 (e.g., a>b). In another example, the distance “a” between first array 302 and second array 304 is equal to or smaller than the distance “b” between two adjacent first mark units 308 in first array 302 or second array 304 (e.g., a≤b).

Alternatively or additionally, a distance “c” between fourth array 360 and first array 302 in the Y-direction can be different from the distance “b” between two adjacent first mark units 308 in first array 302 or fourth array 360 in the Y-direction. For example, the distance “c” between fourth array 360 and first array 302 is greater than the distance “b” between two adjacent mark units 308 in first array 302 or fourth array 360 (e.g., c>b). In another example, the distance “c” between fourth array 360 and first array 302 is equal to or smaller than the distance “b” between two adjacent mark units 308 in first array 302 or fourth array 308 (e.g., c≤b). The distance “c” may be smaller than, equal to, or greater than the distance “a,” which is not limited herein.

In some implementations, first array 302 and third array 306 of first mark units 308B may include a first material different from a second material of second array 304 of first mark units 308A. Alternatively or additionally, fourth array 360 and fifth array 362 of first mark units 308C may include a third material different from the first material or the second material. In some other implementations, first array 302 and third array 306 of first mark units 308B may include the same material as that of second array 304 of first mark units 308A. Alternatively or additionally, fourth array 360 and fifth array 362 of first mark units 308C may include the same material as that of first and third arrays 302, 306 of first mark units 308B or that of second array 304 of first mark units 308A. It is contemplated that the material of first mark units 308A, 308B, 308C can be determined according to the actual process steps needed to form respective patterns in target layer 312, first reference layer 310, and a second reference layer 365 (shown in FIG. 3F), which is not limited herein.

In some implementations, first mark units 308B in first array 302 and third array 306 may be arranged in one or more first semiconductor layers. First mark units 308A in second array 304 are arranged in one or more second semiconductor layers different from the one or more first semiconductor layers. Fourth and fifth arrays 360, 362 of first mark units 308C are arranged in one or more third semiconductor layers different from at least one of the one or more first semiconductor layers or the one or more second semiconductor layers. For example, with reference to FIG. 3F, first mark units 308B in first array 302 and third array 306 may be arranged in first reference layer 310 including semiconductor layers 314 and 315. First mark units 308A in second array 304 are arranged in target layer 312 including semiconductor layers 316, 317, and 318. Fourth and fifth arrays 360 and 362 of first mark units 308C are arranged in second reference layer 365 including a semiconductor layer 367. It is contemplated that first mark units 308A, 308B, and 308C may be arranged in the same semiconductor layer(s) or different semiconductor layers, according to actual process steps needed to form respective patterns in target layer 312, first reference layer 310, and second reference layer 365, which is not limited herein.

With reference to FIG. 3F, first and third arrays 302, 306 of first mark units 308B may include patterns formed by one or more first process steps associated with first reference layer 310, and second array 304 of first mark units 308A may include patterns formed by one or more second process steps associated with target layer 312. Similarly, fourth and fifth arrays 360, 362 of first mark units 308C may include patterns formed by one or more third process steps associated with second reference layer 365. Second reference layer 365 may be below first reference layer 310. In some implementations, first mark units 308C may be formed in second reference layer 365 firstly. Next, first reference layer 310 may be deposited on second reference layer 365. First mark units 308B may be formed in first reference layer 310. Subsequently, target layer 312 may be deposited on first reference layer 310. First mark units 308A can be formed in target layer 312.

In some implementations, first mark 206 shown in FIGS. 3E-3F can be arranged within respective dies of memory device 200, or in cutting streets between respective dies of memory device 200. When first mark 206 shown in FIGs. FIGS. 3E-3F is rotated by 90 degrees, the rotated first mark 206 becomes second mark 204 (e.g., a rotated first mark unit 308 becomes a corresponding second mark unit 307). As a result, second mark 204 further includes (i) a fourth array of second mark units arranged at a first end of the mark and adjacent to first array 303 of second mark units 307B in the X-direction and (ii) a fifth array of second mark units arranged at a second end of the mark and adjacent to third array 309 of second mark units 307B in the X-direction. The similar description for second mark 204 will not be repeated herein.

FIG. 4A illustrates a top view of a first implementation of a memory device 400, according to some aspects of the present disclosure. Memory device 400 can be an example implementation of memory device 200 of FIG. 2. Memory device 400 may include a die 401. Although only one die is shown in FIG. 4A, memory device 400 may include a plurality of dies, which is not limited herein. Die 401 may include a plurality of banks 202A-202J in a plurality of bank regions, respectively. Marks may be arranged within die 401. For example, marks can be arranged in a plurality of peripheral regions 403, where the plurality of peripheral regions 403 may include blank regions (or dummy regions) outside and surrounding respective banks 202A-202J. Although eighty marks (labeled using numbers 1-80) are illustrated in FIG. 4A, it is understood that die 401 may include any number of marks, which is not limited herein.

Each of the marks 1-40 extends in the Y-direction, and the length of each mark 1-40 in the Y-direction is greater than the length of the mark in the X-direction. For example, the marks 1-40 may be first marks 206. On the other hand, each of the marks 41-80 extends in the X-direction, and the length of each mark 41-80 in the X-direction is greater than the length of the mark in the Y-direction. For example, the marks 41-80 may be second marks 204.

In some implementations, the marks 1-80 are arranged to be symmetric relative to a center line F-F′ of die 401 in the X-direction. Alternatively or additionally, the marks 1-80 are arranged to be symmetric relative to a center line E-E′ of die 401 in the Y-direction. In some other implementations, the marks 1-80 are arranged to be unsymmetric relative to the center line E-E′ or the center line F-F′ of die 401, which is not limited herein.

FIG. 4B illustrates an enlarged view of a first portion 402 of memory device 400 of FIG. 4A, according to some aspects of the present disclosure. First portion 402 shows that the mark 10 (e.g., an example of first mark 206) and the mark 50 (e.g., an example of second mark 204) are arranged in a peripheral region 403 outside and surrounding bank 202E. For example, the mark 10 and the mark 50 are arranged in an upper right corner of peripheral region 403.

FIG. 4C illustrates an enlarged view of a second portion 404 of memory device 400 of FIG. 4A, according to some aspects of the present disclosure. Second portion 404 shows that the mark 28 (e.g., an example of first mark 206) and the mark 68 (e.g., an example of second mark 204) are arranged in a peripheral region 403A outside and surrounding bank 202I. For example, the mark 28 and the mark 68 are arranged in an upper right corner of peripheral region 403A. Second portion 404 also shows that the mark 29 (e.g., an example of first mark 206) and the mark 69 (e.g., an example of second mark 204) are arranged in a peripheral region 403B outside and surrounding bank 202J. For example, the mark 29 and the mark 69 are arranged in an upper left corner of peripheral region 403B.

FIG. 4D illustrates a top view of a second implementation of memory device 400, according to some aspects of the present disclosure. Compared with FIG. 4A, there are limited blank regions (or dummy regions) within die 401. Marks (labeled with the numbers 1-8) may be arranged in blank regions (or dummy regions) around the four corners of die 401. The marks 1-4 may be first marks 206, whereas the marks 5-8 may be second marks 204.

FIG. 5 illustrates a top view of a memory device 500 including a plurality of marks arranged in cutting streets 504 of memory device 500, according to some aspects of the present disclosure. Memory device 500 may include a plurality of dies 502 (e.g., 3×5 dies) separated by cutting streets 504. Marks may be arranged in cutting streets 504 of respective dies 502. Although thirty-eight marks (labeled using numbers 1-38) are illustrated in FIG. 5, it is understood that memory device 500 may include any number of marks, which is not limited herein. An enlarged view of a portion 506 of memory device 500 is also shown, in which the mark 5 is arranged in cutting street 504 between dies 502.

Each of the marks 19-39 extends in the Y-direction, and the length of each mark 19-39 in the Y-direction is greater than the length of the mark in the X-direction. For example, the marks 19-39 may be first marks 206. On the other hand, each of the marks 1-18 extends in the X-direction, and the length of each mark 1-18 in the X-direction is greater than the length of the mark in the Y-direction. For example, the marks 1-18 may be second marks 204.

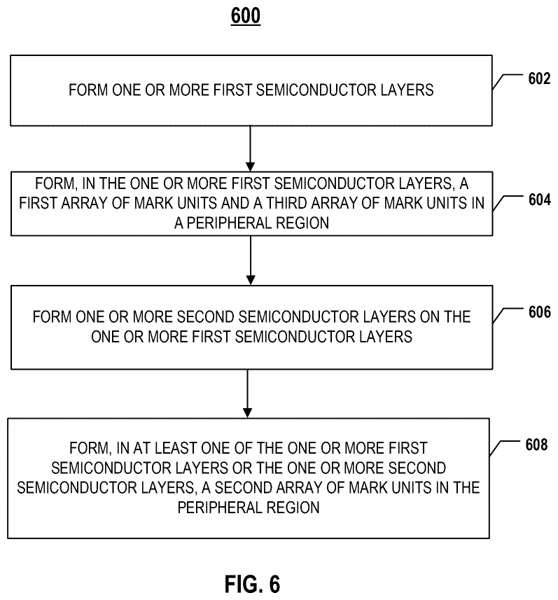

FIG. 6 illustrates a flowchart of a method 600 for forming a memory device, according to some aspects of the present disclosure. The memory device can be any memory device disclosed herein, such as memory device 200, 400, or 500. It is understood that the operations shown in method 600 are not exhaustive and that other operations can be performed as well before, after, or between any of the illustrated operations. Further, some of the operations may be performed simultaneously, or in a different order than shown in FIG. 6. FIGS. 7A-7J illustrate a fabrication process for forming a memory device, according to some aspects of the present disclosure. FIGS. 6 and 7A-7J are described together.

In some implementations, forming the memory device may include forming a bank in a bank region. In some implementations, forming the memory device may also include forming a mark extending in a first direction in a peripheral region that is around the bank region. The mark may include a first array of mark units, a second array of mark units, and a third array of mark units arranged in the first direction. Operations 602-608 of method 600 may be performed to form the mark.

As shown in FIG. 6, method 600 can start at operation 602, in which one or more first semiconductor layers can be formed. Next, method 600 can proceed to operation 604, in which a first array of mark units and a third array of mark units can be formed in the one or more first semiconductor layers in the peripheral region. For example, forming the first array of mark units and the third array of mark units may include forming, in the one or more first semiconductor layers, a first set of openings and a second set of openings arranged in the first direction; and forming the first array of mark units in the first set of openings, respectively, and the third array of mark units in the second set of openings, respectively.

With reference to FIG. 7A, a first reference layer 702 including semiconductor layers 704 and 706 can be formed by depositing semiconductor layer 706 on semiconductor layer 704. In some implementations, semiconductor layer 704 can be a substrate that can include silicon (e.g., single crystalline silicon, c-Si), SiGe, GaAs, Ge, SOI, or any other suitable materials. Semiconductor layer 706 may include silicon oxide or any other suitable semiconductor material, which is not limited herein. A photoresist layer 708 can be formed on semiconductor layer 706 and patterned to form openings 710 to expose semiconductor layer 706.

The substrate of the memory device includes two lateral surfaces extending laterally in the x-y plane: a top surface on the front side of the wafer on which the semiconductor devices can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of the memory device is determined relative to the substrate of the memory device in the z-direction (the vertical direction perpendicular to the x-y plane, e.g., the thickness direction of the substrate) when the substrate is positioned in the lowest plane of the memory device in the z-direction. The same notion for describing the spatial relationships is applied throughout the present disclosure.

With reference to FIG. 7B, openings 712 may be formed in semiconductor layer 706. For example, semiconductor layer 706 may be etched through openings 710 of photoresist layer 708 (shown in FIG. 7A) to form openings 712 in semiconductor layer 706. In some implementations, fabrication processes for forming openings 712 include wet etching and/or dry etching, such as deep-ion reactive etching (DRIE). Then, photoresist layer 708 can be removed to expose semiconductor layer 706.

With reference to FIG. 7C, openings 714 may be formed in semiconductor layer 704. For example, semiconductor layer 704 may be etched through openings 712 of semiconductor layer 706 (shown in FIG. 7B) to form openings 714 in semiconductor layer 704. In some implementations, fabrication processes for forming openings 714 include wet etching and/or dry etching, such as DRIE. Then, semiconductor layer 706 can be removed to expose semiconductor layer 704.

With reference to FIG. 7D, a material layer 716 may be formed on semiconductor layer 704. For example, material layer 716 may be formed by filling openings 714 with a dielectric material and depositing a layer of the dielectric material on semiconductor layer 704, using one or more thin film deposition processes including, but not limited to, chemical vapor deposition (CVD), physical vapor deposition (PVD), atomic layer deposition (ALD), or any combination thereof. The dielectric material may include, for example, silicon oxide, silicon nitride, or any other suitable dielectric material, which is not limited herein. In another example, material layer 716 may be formed by filling openings 714 with a conductive material and depositing a layer of the conductive material on semiconductor layer 704, using one or more thin film deposition processes including, but not limited to, CVD, PVD, ALD, or any combination thereof. The conductive material may include, for example, tungsten (W), copper (Cu), aluminum (Al), or any other suitable conductive material, which is not limited herein.

With reference to FIG. 7E, Chemical Mechanical Planarization (CMP) may be performed on semiconductor layer 704 to remove a portion of material layer 716 deposited on top of semiconductor layer 704. Then, a first array 720 of mark units 718B and a third array 722 of mark units 718B are formed in semiconductor layer 704. Each mark unit 718B may include the dielectric material (or conductive material) filled in a respective opening 714 as described above with reference to FIG. 7D.

As shown in FIG. 6, method 600 can proceed to operation 606, in which one or more second semiconductor layers can be formed on the one or more first semiconductor layers. Next, method 600 can proceed to operation 608, in which a second array of mark units can be formed in at least one of the one or more first semiconductor layers or the one or more second semiconductor layers in the peripheral region. For example, forming the second array of mark units may include forming, in the at least one of the one or more first semiconductor layers or the one or more second semiconductor layers, a third set of openings arranged in the first direction, where the third set of openings is formed between the first and third arrays of mark units in the first direction; and forming the second array of mark units in the third set of openings, respectively.

With reference to FIG. 7F, a target layer 724 (including semiconductor layers 726, 728, and 730) can be formed by depositing semiconductor layers 726, 728, and 730 on semiconductor layer 704. In some implementations, semiconductor layer 726 can include silicon nitride or any other suitable semiconductor material, which is not limited herein. Semiconductor layer 728 may include spin-on carbon (SOC) or any other suitable semiconductor material, which is not limited herein. Semiconductor layer 730 may include silicon oxynitride (SiON) or any other suitable semiconductor material, which is not limited herein. A photoresist layer 732 can be formed on semiconductor layer 730 and patterned to form openings 734 to expose semiconductor layer 730.

With reference to FIG. 7G, openings 736 may be formed in semiconductor layers 704, 726, 728, and 730. For example, semiconductor layers 704, 726, 728, and 730 may be etched through openings 734 of photoresist layer 732 (shown in FIG. 7F) to form openings 736 in semiconductor layers 704, 726, 728, and 730. In some implementations, fabrication processes for forming openings 736 include wet etching and/or dry etching, such as DRIE. Then, photoresist layer 732 can be removed to expose semiconductor layer 730. Semiconductor layers 730, 728, and 726 may also be removed to expose semiconductor layer 704.

With reference to FIG. 7H, one or more material layers may be filled in openings 736 in semiconductor layer 704, using one or more thin film deposition processes including, but not limited to, CVD, PVD, ALD, or any combination thereof. In some implementations, the one or more material layers may include, for example, one or more conductive layers such as a titanium nitride (TiN) layer, a tungsten (W) layer, a copper (Cu) layer, an aluminum (Al) layer, or any other suitable conductive material, which is not limited herein. Then, a second array 738 of mark units 718A is formed in semiconductor layer 704. Each mark unit 718A may include the one or more material layers.

In some implementations, the process steps in FIGS. 7G and 7H may be replaced by process steps described below with reference to FIGS. 7I and 7J. With reference to FIG. 7I, instead of forming openings 736 in semiconductor layers 704, 726, 728, and 730 in FIG. 7G, openings 740 may be formed in semiconductor layers 726 and 728. For example, semiconductor layers 726 and 728 may be etched through openings 734 of photoresist layer 732 (shown in FIG. 7F) to form openings 740 in semiconductor layers 726 and 728. In some implementations, fabrication processes for forming openings 740 include wet etching and/or dry etching, such as DRIE. Then, photoresist layer 732 can be removed to expose semiconductor layer 730.

With reference to FIG. 7J, one or more material layers may be filled in openings 740, using one or more thin film deposition processes including, but not limited to, CVD, PVD, ALD, or any combination thereof. In some implementations, the one or more material layers may include, for example, one or more conductive layers such as a titanium nitride (TiN) layer, a tungsten (W) layer, a copper (Cu) layer, an aluminum (Al) layer, or any other suitable conductive material, which is not limited herein. Second array 738 of mark units 718A is formed in semiconductor layers 728 and 730. Each mark unit 718A may include the one or more material layers.

As a result, the mark is formed in the memory device, which includes first array 720 of mark units 718B, second array 738 of mark units 718A, and third array 722 of mark units 718B. The mark can be, for example, first mark 206 or second mark 204 disclosed herein. The mark is applicable in a manufacturing process associated with a 3D memory device (such as a 3D NAND flash memory device or a 3D DRAM memory device). Examples of the manufacturing process include, but are not limited to, a Litho-Etch (LE) process, a Litho-Etch-Litho-Etch (LELE) process, a Self Align Double Patterning (SADP) process, a Self Align Reverse double Patterning (SARP) process, a Self Align Quadruple Patterning (SAQP) process, etc. It is contemplated that the process steps described above with reference to FIGS. 7A-7J for forming the mark are only used for illustration purposes. Other process steps may be performed to form the mark according to actual need, which is not limited herein.

With reference to FIG. 7F, a first overlay measurement may be performed after photoresist layer 732 is patterned to form openings 734. A first overlay error may be determined based on first array 720 of mark units 718B, third array 722 of mark units 718B, and openings 734. In this case, if the first overlay error is greater than a preset threshold, the lithography equipment may be adjusted to improve overlay alignment. Afterwards, with reference to FIG. 7H or 7J, a second overlay measurement may be performed after second array 738 of mark units 718A is formed. A second overlay error may be determined based on first array 720 of mark units 718B, third array 722 of mark units 718B, and second array 738 of mark units 318A. The lithography equipment may also be adjusted based on the second overlay error to improve overlay alignment.

With reference to FIG. 6 again, in some implementations, a first reference layer (including the one or more first semiconductor layers) formed in operation 602 are deposited on a second reference layer (including one or more third semiconductor layers). That is, before forming the one or more first semiconductor layers, the second reference layer (including the one or more third semiconductor layers) is formed, and forming the mark further includes forming, in the one or more third semiconductor layers, a fourth array of mark units at a first end of the mark and a fifth array of mark units at a second end of the mark in the first direction. In this case, the mark may further include the fourth array of mark units and the fifth array of mark units.

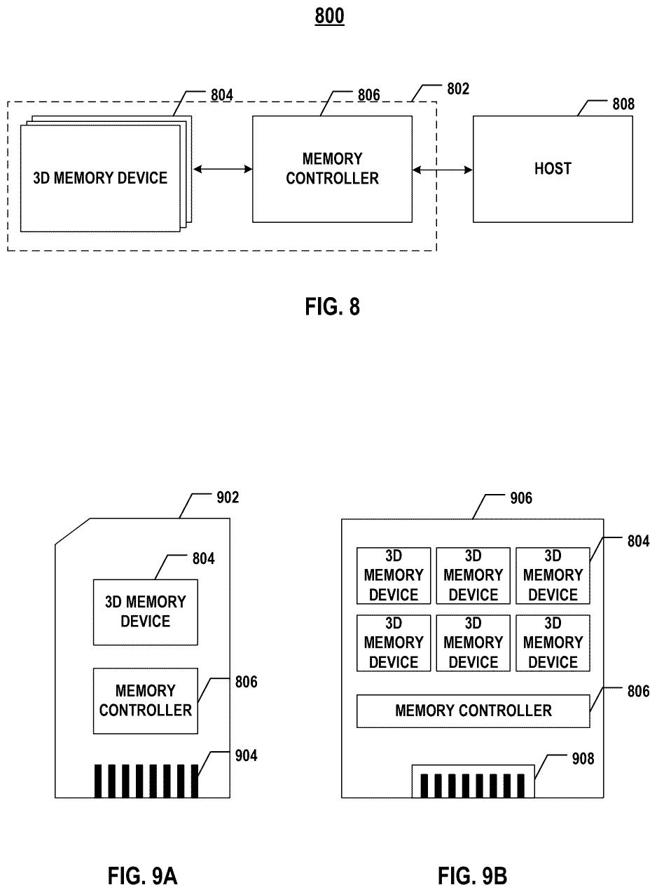

FIG. 8 illustrates a block diagram of an exemplary system 800 having a 3D memory device, according to some aspects of the present disclosure. System 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, system 800 can include a host 808 and a memory system 802 having one or more 3D memory devices 804 and a memory controller 806. Host 808 can be a processor of an electronic device, such as a central processing unit (CPU), or a system-on-chip (SoC), such as an application processor (AP). Host 808 can be configured to send or receive data to or from 3D memory devices 804.

3D memory device 804 can be any 3D memory device disclosed herein, such as memory device 200 of FIG. 2, memory device 400 of FIG. 4A or 4D, or memory device 500 of FIG. 5. In some implementations, each 3D memory device 804 includes a NAND Flash memory or a DRAM memory device.

Memory controller 806 (a.k.a., a controller circuit) is coupled to 3D memory device 804 and host 808 and is configured to control 3D memory device 804, according to some implementations. For example, memory controller 806 may be configured to operate the plurality of channel structures via the word lines. Memory controller 806 can manage the data stored in 3D memory device 804 and communicate with host 808. In some implementations, memory controller 806 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed for operating in a high duty-cycle environment SSDs or embedded multi-media-cards (eMMCs) used as data storage for mobile devices, such as smartphones, tablets, laptop computers, etc., and enterprise storage arrays. Memory controller 806 can be configured to control operations of 3D memory device 804, such as read, erase, and program operations. Memory controller 806 can also be configured to manage various functions with respect to the data stored or to be stored in 3D memory device 804 including, but not limited to bad-block management, garbage collection, logical-to-physical address conversion, wear leveling, etc. In some implementations, memory controller 806 is further configured to process error correction codes (ECCs) with respect to the data read from or written to 3D memory device 804. Any other suitable functions may be performed by memory controller 806 as well, for example, formatting 3D memory device 804. Memory controller 806 can communicate with an external device (e.g., host 808) according to a particular communication protocol. For example, memory controller 806 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 806 and one or more 3D memory devices 804 can be integrated into various types of storage devices, for example, be included in the same package, such as a universal Flash storage (UFS) package or an eMMC package. That is, memory system 802 can be implemented and packaged into different types of end electronic products. In one example as shown in FIG. 9A, memory controller 806 and a single 3D memory device 804 may be integrated into a memory card 902. Memory card 902 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 902 can further include a memory card connector 904 electrically coupling memory card 902 with a host (e.g., host 808 in FIG. 8). In another example as shown in FIG. 9B, memory controller 806 and multiple 3D memory devices 804 may be integrated into an SSD 906. SSD 906 can further include an SSD connector 908 electrically coupling SSD 906 with a host (e.g., host 808 in FIG. 8). In some implementations, the storage capacity and/or the operation speed of SSD 906 is greater than those of memory card 902.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a bank in a bank region; and
one or more first marks of a first type and one or more second marks of a second type, wherein the one or more first marks and the one or more second marks are arranged in a peripheral region around the bank region.

2. The memory device of claim 1, wherein:
at least a first mark from the one or more first marks extends in a first direction, and a length of the first mark in the first direction is greater than a length of the first mark in a second direction intersected with the first direction; and
at least a second mark from the one or more second marks extends in the second direction, and a length of the second mark in the second direction is greater than a length of the second mark in the first direction.

3. The memory device of claim 2, wherein the peripheral region comprises:
a first peripheral sub-region extending in the first direction;
a second peripheral sub-region extending in the second direction intersected with the first direction, wherein the second peripheral sub-region connects to the first peripheral sub-region outside a first corner of the bank region;
a third peripheral sub-region extending in the first direction, wherein the third peripheral sub-region connects to the second peripheral sub-region outside a second corner of the bank region; and
a fourth peripheral sub-region extending in the second direction, wherein the fourth peripheral sub-region connects to the third peripheral sub-region outside a third corner of the bank region and connects to the first peripheral sub-region outside a fourth corner of the bank region.

4. The memory device of claim 3, wherein the one or more first marks are arranged in at least one of the first peripheral sub-region or the third peripheral sub-region in the first direction, and the one or more second marks are arranged in at least one of the second peripheral sub-region or the fourth peripheral sub-region in the second direction.

5. The memory device of claim 1, wherein the one or more first marks and the one or more second marks are arranged in at least one corner of the peripheral region.

6. The memory device of claim 2, wherein:
the first mark comprises a plurality of first mark units arranged in the first direction, wherein at least one of the first mark units extends in the second direction; and
the second mark comprises a plurality of second mark units arranged in the second direction, wherein at least one of the second mark units extends in the first direction.

7. The memory device of claim 6, wherein the at least one of the first mark units comprises a first bar extending in the second direction, and the at least one of the second mark units comprises a second bar extending in the first direction.

8. The memory device of claim 6, wherein the at least one of the first mark units comprises two or more first rectangles or first squares arranged in the second direction, and the at least one of the second mark units comprises two or more second rectangles or second squares arranged in the first direction.

9. The memory device of claim 6, wherein the plurality of first mark units comprise a first array of first mark units, a second array of first mark units, and a third array of first mark units, wherein the second array of first mark units is arranged between the first and third arrays of first mark units in the first direction.

10. The memory device of claim 9, wherein the first and third arrays of first mark units comprise a material different from that of the second array of first mark units.

11. The memory device of claim 10, wherein the first and third arrays of first mark units comprise silicon oxide, tungsten (W), or copper (Cu), and the second array of first mark units comprises titanium nitride (TiN) and W.

12. The memory device of claim 9, wherein the first and third arrays of first mark units are arranged in one or more semiconductor layers different from that of the second array of first mark units.

13. The memory device of claim 12, wherein in the first direction, a distance between the first array of first mark units and the second array of first mark units is greater than a distance between two adjacent first mark units in the first or second array of first mark units.

14. A memory device, comprising:
a bank in a bank region; and
a mark arranged in a peripheral region that is around the bank region, and comprising a first array of mark units, a second array of mark units, and a third array of mark units arranged in a first direction, wherein the second array of mark units is arranged between the first array of mark units and the third array of mark units in the first direction.

15. The memory device of claim 14, wherein a length of the mark in the first direction greater than a length of the mark in a second direction intersected with the first direction.

16. The memory device of claim 14, wherein the mark further comprises:
a fourth array of mark units arranged at a first end of the mark and adjacent to the first array of mark units in the first direction; and
a fifth array of mark units arranged at a second end of the mark and adjacent to the third array of mark units in the first direction.

17. The memory device of claim 16, wherein:
the first and third arrays of mark units are arranged in one or more first semiconductor layers;
the second array of mark units is arranged in one or more second semiconductor layers different from the one or more first semiconductor layers; and
the fourth and fifth arrays of mark units are arranged in one or more third semiconductor layers different from at least one of the one or more first semiconductor layers or the one or more second semiconductor layers.

18. A method for forming a memory device, comprising:
forming a mark in a peripheral region that is around a bank region, wherein the mark comprises a first array of mark units, a second array of mark units, and a third array of mark units arranged in a first direction, wherein forming the mark comprises:
forming one or more first semiconductor layers;
forming, in the one or more first semiconductor layers, the first array of mark units and the third array of mark units in the peripheral region;
forming one or more second semiconductor layers on the one or more first semiconductor layers; and
forming, in at least one of the one or more first semiconductor layers or the one or more second semiconductor layers, the second array of mark units in the peripheral region, wherein the second array of mark units is formed between the first array of mark units and the third array of mark units in the first direction.

19. The method of claim 18, wherein:
forming the first array of mark units and the third array of mark units comprises:
forming, in the one or more first semiconductor layers, a first set of openings and a second set of openings arranged in the first direction; and
forming the first array of mark units in the first set of openings, respectively, and the third array of mark units in the second set of openings, respectively; and
forming the second array of mark units comprises:
forming, in the at least one of the one or more first semiconductor layers or the one or more second semiconductor layers, a third set of openings arranged in the first direction, wherein the third set of openings is formed between the first and third arrays of mark units in the first direction; and
forming the second array of mark units in the third set of openings, respectively.

20. The method of claim 18, wherein:
the one or more first semiconductor layers are formed on one or more third semiconductor layers; and
forming the mark further comprises:
forming, in the one or more third semiconductor layers, a fourth array of mark units at a first end of the mark and a fifth array of mark units at a second end of the mark in the first direction.
